(19) United States
(12) Patent Application Publication
(10) Pub. No.: US 2002/0196950 A1
(43) Pub. Date: Dec. 26, 2002

(54) Method and apparatus for treating an audio signal

(76) Inventor: Henricus Johannes, F. ,G. Groothuis, Spearwood (AU)

Correspondence Address: ALTERA LAW GROUP, LLC, 6500 CITY WEST PARKWAY, SUITE 100, MINNEAPOLIS, MN, 55344-7704, US

(21) Appl. No.: 10/101,129

(22) Filed: Mar. 19, 2002

Related U.S. Application Data
(63) Continuation of application No. PCT/AU00/01146, filed on Sep. 20, 2000.

(30) Foreign Application Priority Data
Sep. 20, 1999 (AU) PQ 2982

(51) Int. Cl. H03G 1/00; H03G 5/00

(52) U.S. Cl. 381/97; 381/98

(57) ABSTRACT

A method of treating an audio signal is disclosed, comprising introducing a phase shift to the audio signal, the magnitude of the phase shift being dependent upon the frequency of the audio signal. A signal control system implementing the method is also disclosed, described for an active loudspeaker having at least one sound transducer, each sound transducer having an amplifier connected directly thereto, the signal control system provided between a signal source and the amplifier and comprising crossover means arranged to deliver a frequency limited portion of the signal to the amplifier; and phase shift means arranged to introduce a frequency dependent phase shift to the signal prior to being input to the amplifier, wherein the magnitude of the phase shift is dependent upon the frequency of the audio signal. The method and system increases the perceived clarify of the sound by the listener.

### FIELD OF THE INVENTION

This invention relates to a method and apparatus for treating an audio signal, particularly, although not exclusively, in a signal control system for an active loudspeaker.

### BACKGROUND ART

The majority of loudspeakers commercially available are passive, that is loudspeakers without any active amplification circuitry. The loudspeakers typically include several sound transducers or “drivers” and a crossover circuit to distribute the signal between the drivers according to frequency. A separate amplifier is required, in addition to the passive loudspeakers, in order to amplify a signal source to a sufficient level to reproduce the sound at a desired level.

The crossover circuit usually includes circuitry to compensate for non-linearities in the drivers, such as compensation networks. This additional circuitry complicates the crossover circuit. Further, crossover circuits are inefficient and can absorb as much as 60% of the power from the amplifier. The presence of the crossover circuit between the amplifier and the drivers reduces the control the amplifier has over the motion of the drivers, which can result in the loudspeakers sounding muffled and dull.

One of the perceived criteria of good sound reproduction is time alignment. Time alignment refers to sounds at different frequencies, which occur simultaneously in the signal source, arriving simultaneously at the listener's ear. Time alignment influences the clarity and liveliness of the sound perceived by the listener. Time alignment is a subjective criterion to some extent.

The current approach to time alignment is to reduce or eliminate any phase shift between the signal source and the drivers. Accordingly, it is common practice for the crossover circuit to be designed so that it introduces a fixed phase shift to the signal for a particular driver (eg woofer, midrange, tweeter), or that any phase shift is constant across the frequency range of the loudspeakers.

Another technique used in achieving time alignment is the physical placement of the drivers in a loudspeaker. By adjusting the distance between each driver and listener, a phase delay between the signals issuing from the respective drivers is achieved. This most commonly takes the form of recessing the tweeter with respect to the other drivers of a loudspeaker. This achieves a constant phase delay from all frequencies reproduced by the tweeter relative to the other drivers.

Recently, audio signal processing systems have become popular. Such systems are commonly termed surround-sound controllers, which provide for at least 4 channels, namely left and right front and left and right rear. Depending upon the surround-sound controller, further channels may also be provided. Many surround-sound controllers provide for a phase shift between signals in the front and rear channels, which is typically user adjustable between 15 and 30 milliseconds. The phase shift is constant with respect to frequency. That is, the same phase shift is applied to low frequency signals as to high frequency signals. This delay is deliberately designed to not provide time alignment between the front and rear channels so as to provide a perception of spaciousness.

### DISCLOSURE OF THE INVENTION

Throughout the specification, unless the context requires otherwise, the word “comprise” or variations such as “comprises” or “comprising”, will be understood to imply the inclusion of a stated integer or group of integers but not the exclusion of any other integer or group of integers.

According to one aspect of the invention, there is provided a method of treating an audio signal, comprising introducing a phase shift to the audio signal, the magnitude of the phase shift being dependant upon the frequency of the audio signal.

Preferably, the audio signal is divided into a plurality of portions before introducing the frequency-dependant phase shift, the frequency-dependant phase shift being introduced to each portion.

The magnitude of the frequency-dependant phase shift may be proportional to the exponential of the frequency, or proportional to the logarithm of the frequency. Alternatively, it may be linearly proportional, or piecewise-linearly proportional to the frequency.

Further, the frequency-dependant phase shift may be a piecewise-linear approximation of the logarithm, or exponential, of the frequency.

The magnitude of the frequency-dependant phase shift may monotonically, or piecewise monotonically, be dependant upon the frequency.

In another aspect of the present invention, there is provided a signal control system for an active loudspeaker having at least one sound transducer, each sound transducer having an amplifier connected directly thereto, the signal control system provided between a signal source and the amplifier and comprising crossover means arranged to deliver a frequency limited portion of the signal to the amplifier; and phase shift means arranged to introduce a frequency dependent phase shift to the signal prior to being input to the amplifier, wherein the magnitude of the phase shift is dependant upon the frequency of the audio signal.

The phase shift means may be provided integral with the crossover means.

The crossover means may comprise an active crossover circuit, and the active crossover circuit may comprise a plurality of operational amplifiers and associated bias circuitry, wherein the operational amplifiers are operable without frequency compensation to thereby introduce a phase shift, and thus the frequency dependent phase shift, to the signal. The crossover circuit may be a fourth order Butterworth circuit, incorporating low pass and high pass filters. This has the advantage of providing better signal-to-noise ratios and less signal distortion.

High end filtering is no longer necessary at the output of the amplifier, other than to prevent external high-frequency interference.

Using an active loudspeaker configuration, the invention provides superior control over the motion of each sound transducer because the output of the amplifier is directly connected to the sound transducer. Thus, short driver leads are required internally, which means that negligible capacitance coupling is produced. The crossover circuit is provided at the input of the amplifier, so that a separate amplifier is used for each sound transducer in the active loudspeaker. In addition, there is extremely accurate feedback, transient response is enhanced, and the impedance curve of the drivers is accurately tracked.

Further, it has been discovered that providing a phase shift that increases with increasing frequency produces a better perceived time alignment by the listener and superior clarity and liveliness to the sound.

In yet another aspect of the present invention, there is provided an active loudspeaker circuit provided between a signal source and a plurality of amplifiers, comprising, crossover means arranged to deliver a frequency limited portion of the signal to each amplifier; and phase shift means arranged to introduce a frequency dependent phase shift to the signal prior to being input to the amplifiers, wherein the frequency dependent phase shift increases with increasing frequency.

### BRIEF DESCRIPTION OF THE DRAWINGS

The invention will now be described with reference to the accompanying drawings, of which:

FIG. 1 is a graph of phase shift against frequency introduced to an audio signal in accordance with a first embodiment of the invention;

FIG. 2 is a graph of phase shift against frequency introduced to an audio signal in accordance with a second embodiment of this invention;

FIG. 3 is a graph of phase shift against frequency introduced to an audio signal in accordance with a third embodiment of this invention;

FIG. 4 is a graph of phase shift against frequency introduced to an audio signal in accordance with a fourth embodiment of this invention;

FIG. 5 is a graph illustrating the effect of treating an audio signal according to the invention;

FIG. 6 is a block diagram of an active loudspeaker including a signal control system utilizing the audio signal treatment method according to the invention;

FIG. 7 shows the signal control system used in the active loudspeaker of FIG. 6;

FIG. 8 is a schematic circuit diagram for a balanced line receiver for the loudspeaker of FIG. 6;

FIG. 9 is a schematic circuit diagram for the amplifiers for the speaker of FIG. 6;

FIG. 10 is a graph of phase shift against frequency introduced to an audio signal input to the active loudspeaker of FIG. 6 and;

FIGS. 11A to 11D are graphs of phase-shift as a function of amplitude for audio signals of selected frequencies input to, and output from, the signal control system of FIG. 7; and

FIG. 12 is a graph of phase-shift as a function of frequency for an audio signal processed by the system of FIG. 7.

### BEST MODE(S) FOR CARRYING OUT THE INVENTION

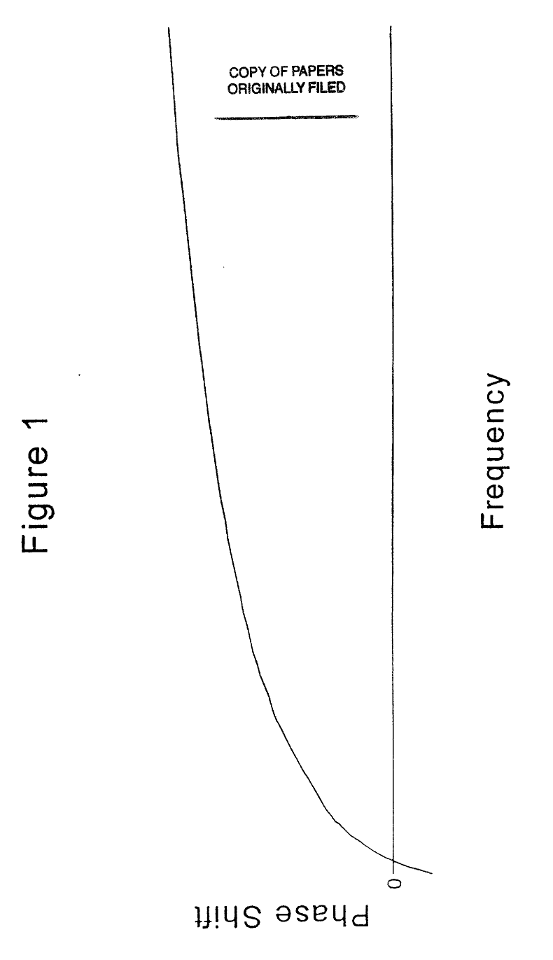

FIG. 1 is a graphical representation of the phase shift, Δφ, introduced in accordance with a method for treating an audio signal which comprises introducing a frequency-dependant phase shift, Δφ, into the audio signal. The horizontal axis represents frequency, F, and the vertical axis represents the magnitude of the phase shift, Δφ.

As shown, the phase shift magnitude, Δφ, introduced to the audio signal is proportional to the logarithm of the frequency, F.

It should be appreciated that the frequency-dependent phase shift, Δφ, spreads out the frequency components of the signal over time.

The treatment of the audio signal can be applied in any desired manner. For instance, the signal can be applied using a digital signal processing system or by use of an operational amplifier that is not frequency compensated and produces a phase shift substantially equivalent to that shown in FIG. 1. Alternatively, a suitable circuit could be incorporated into a monolithic integrated circuit.

It has been found that by treating the left and right channels of a stereophonic audio signal in this manner, the frequency-dependant phase shift produces a better perception of time alignment at the listener's ear. Accordingly, this treatment provides superior imaging and depth of sound field to the listener.

It is believed that this improved perception of the sound is due to the non-linear nature of the ear. If sounds arrive at the ear in a phase aligned manner, harmonic distortions occur within the ear, particularly with high sound levels. Further, the inventor believes speech is a non-phase aligned sound when produced. This is because of the phase control affected by a person between the front of the mouth and the back of the throat. For example, an ‘rrrrr’ sound is created at the back of the throat, while an ‘ssss’ sound is created at the front of the mouth. This results in a relative phase difference between the two sounds. It is believed that the ear uses this phase difference in perceiving the sound.

By treating an audio signal so that different frequency components of the signal have different phase shifts, harmonic distortions within the ear are eliminated or at least significantly reduced. Further, because of the spreading out of the frequency components over time, interference between harmonic components in the signal is reduced, with the result that the sound propagates through the air with improved clarity, particularly over long distances. This allows the listener to better discern the sound. Listening tests have shown that hearing-impaired people are able to discern the sound with improved clarity if it is treated according the invention. Further, the invention may able be useful in public address systems used in large areas, to improve the sound clarity.

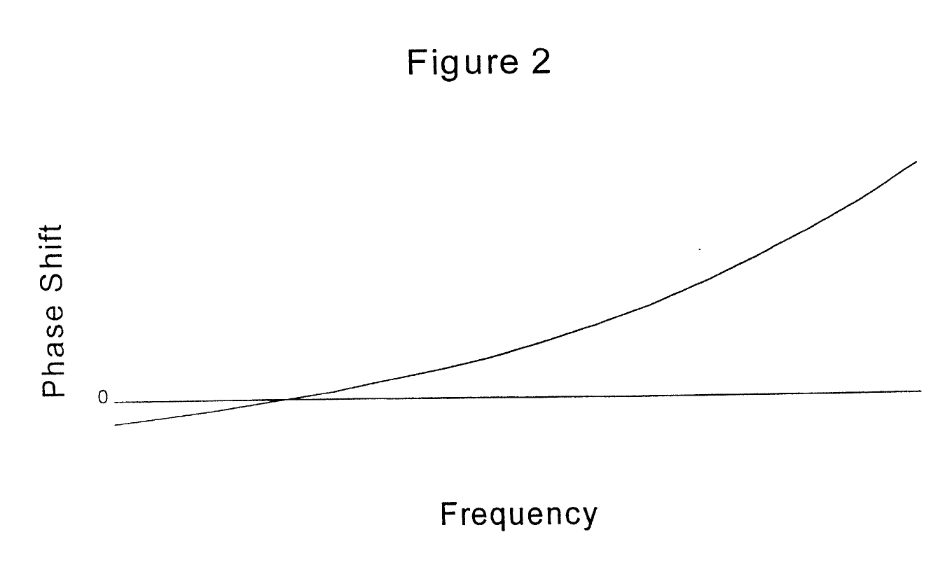

In a second embodiment, the method is substantially the same as that described in relation to the first embodiment. However, the phase shift, Δφ, introduced in this second embodiment is proportional to the exponential of the frequency, F, as shown in the graph of FIG. 2.

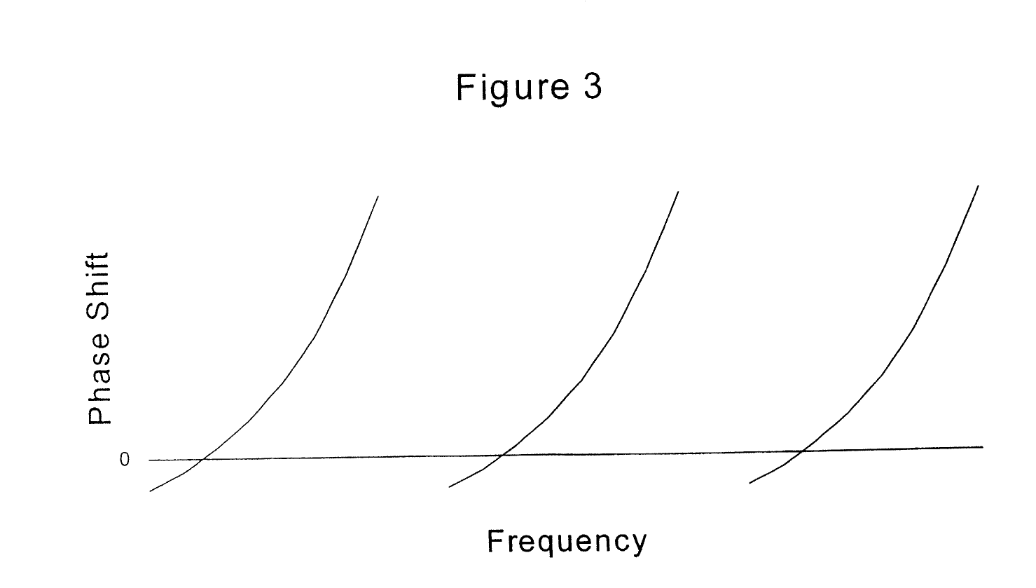

In a third embodiment—illustrated in FIG. 3—the method comprises dividing the audio signal into three portions and introducing a frequency-dependant phase shift, Δφ, into each portion. The frequency-dependant phase shift, Δφ, introduced to each portion increases with increasing frequency within that portion, and, in this embodiment, the phase shift, Δφ, in each portion is proportional to the exponential of the frequency, F. However, the phase shift, Δφ, introduced at the lowest frequency in each portion is the same, so that in effect there is a “resetting” of the phase shift at the beginning of each portion. Within each portion, the phase shift, Δφ, increases monotonically with increasing frequency. In the embodiment shown in FIG. 3, the phase shift, Δφ, at the commencement of each portion is the same. However, the phase shift, Δφ, at the commencement of each portion may have different values as desired.

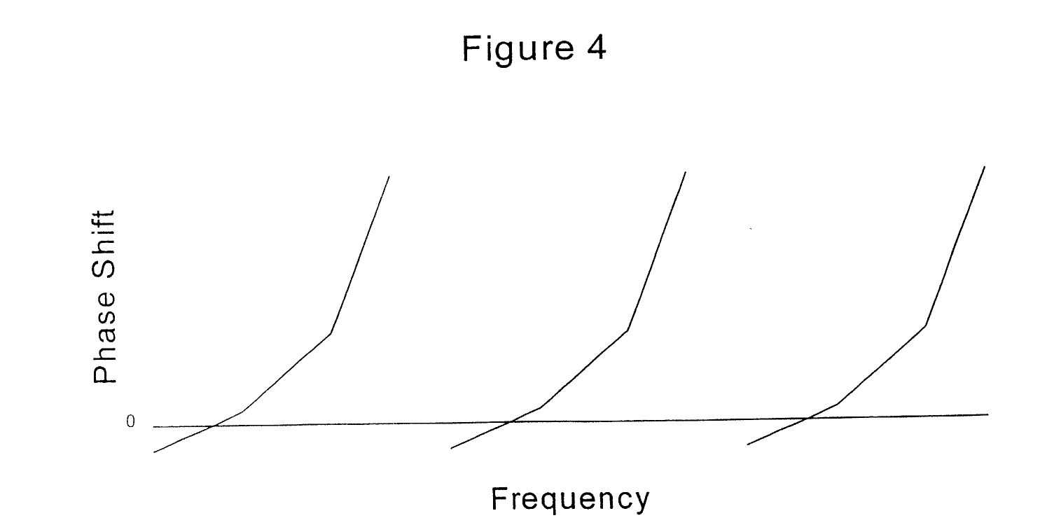

A fourth embodiment—illustrated in FIG. 4—is directed towards a method for treating an audio signal in substantially the same manner as that described in relation to the third embodiment—in that the audio signal is divided into three portions, and that a phase shift, Δφ, is introduced into each of the three portions.

In the fourth embodiment, this phase shift, Δφ, is a piece-wise linear approximation of the exponential of the frequency. This may be desirable to reduce the complexity of the circuit that provides the phase shift, or to simplify its implementation in a digital signal processing system.

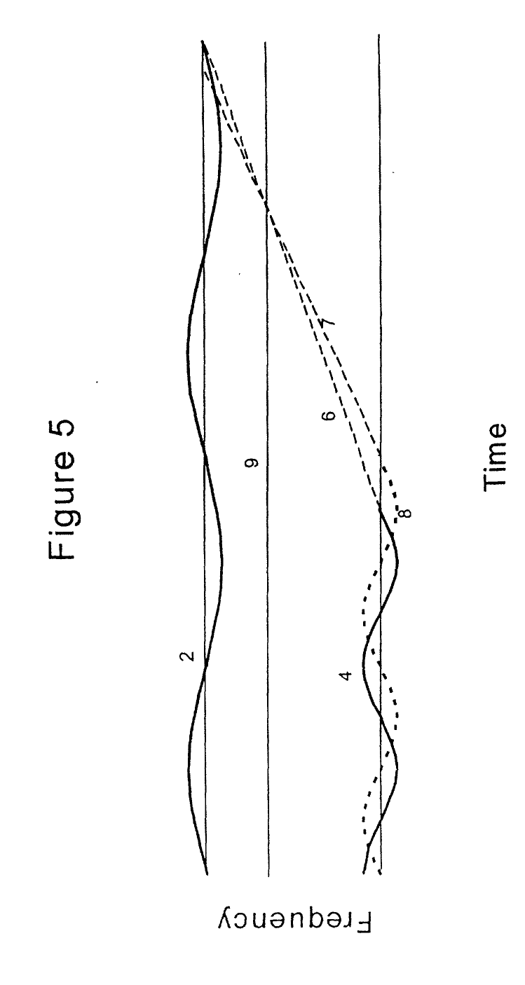

FIG. 5 illustrates the effect of treating an audio signal according to any one of the embodiments described above. The graph shows phase, φ, as a function of frequency, F. A relatively low frequency signal 2 is shown, which may represent the lower end of an audio spectrum, for example 15 Hz. A relatively high frequency signal 4 is shown, which may represent the upper end of an audio spectrum, for example 28 kHz. The signal 4 is not shown to scale for clarity.

Two cycles of the signals 2 and 4 are shown. The high frequency signal 4 is shorter than the low frequency signal 2 because of its higher frequency and hence shorter period.

A dashed line 6 connects the end of the signal 2 to the end of the signal 4. This line 6 represents the ends of two cycles of signals having frequencies intermediate that of the signals 2 and 4.

The signal 4 after being treated according to one of the embodiments is shown in FIG. 5 as the broken line 8. As shown, a phase shift, Δφ, of ¼ period has been applied to the signal 4 to produce a further signal represented by the line 8. A further dashed line 7 extends from the end of the signal 8 to slightly before the end of the signal 2. The gap between the dashed lines 6 and 7 represents the amount of phase shift, Δφ, applied to the different frequency components of an audio signal. As shown, the lines 6 and 7 cross at a point denoted by line 9, which corresponds with no phase shift at that frequency. Above the line 9, the phase shift becomes negative, and a compression of a portion of the signal is used to produce this negative phase shift, as described in more detail below.

In this regard, although the line 18 is shown as a straight line, it should be appreciated that this is simply to represent the different phase shifts applied at different frequencies. Although, in this illustration, the phase shift, Δφ, is linear with frequency, any of the frequency-dependent phase shifts described in the first through fourth embodiments could be applied to the audio signal, as well as, for example, phase shifts which are piecewise-linearly proportional to the frequency, or piecewise linear approximations of the logarithm or exponential of the frequency. Where the phase shift, Δφ, increases monotonically, this could also be piecewise.

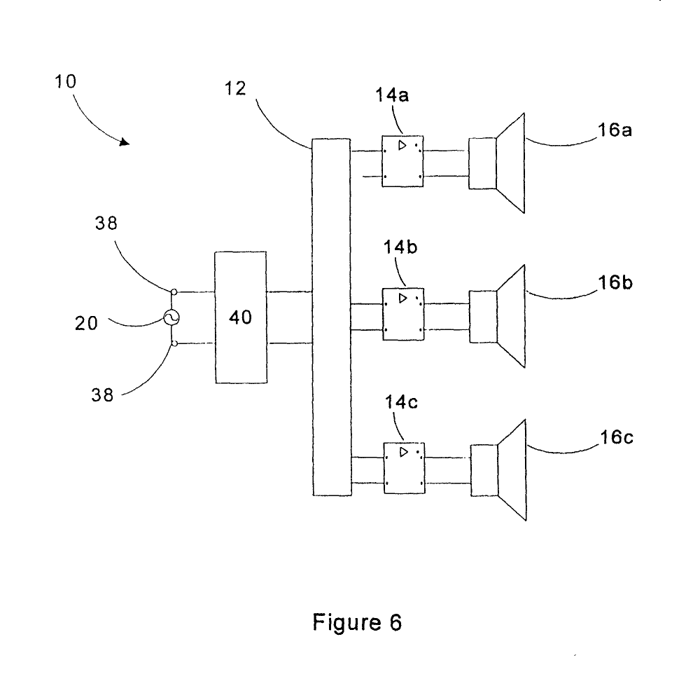

An active loudspeaker 10 incorporating a signal control system 12 utilizing the method described above is now described with reference to FIGS. 6 to 12.

FIG. 6 is a block diagram of the active loudspeaker 10. As shown, the active loudspeaker 10 comprises the signal control system 12, three amplifiers 14a, 14b and 14c and three drivers 16a, 16b and 16c. In the embodiment described herein, the drivers 16a, 16b and 16c are chosen to be a tweeter, a mid-range and a woofer, respectively. Examples of suitable, commercially available, drivers are the D904-980000 tweeter, the 18W-8545 midrange and the M22WR-09-08 woofer manufactured by Vifascan. It should be appreciated, however, that in other embodiments other combinations, types and numbers of drivers could be used.

The signal control system 12 is connected to input terminals 38 of the loudspeaker 10 via a balanced line receiver 40. A signal source 20, such as the signal-level output of a compact disc player is connected to the input terminals 38 to provide a signal to the active loudspeaker 10.

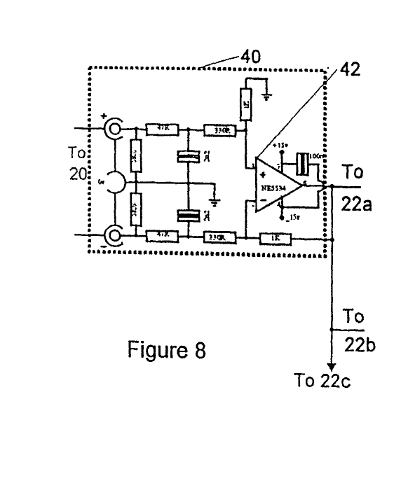

FIG. 8 is a circuit diagram of a suitable receiver 40, although other suitable receivers could be used. The receiver 40 comprises an NE5534 operational amplifier 42, and associated circuitry, including capacitors 44, and resistors 46. The receiver 40 receives the audio signal from the source 20, and outputs a signal to the signal control system 12.

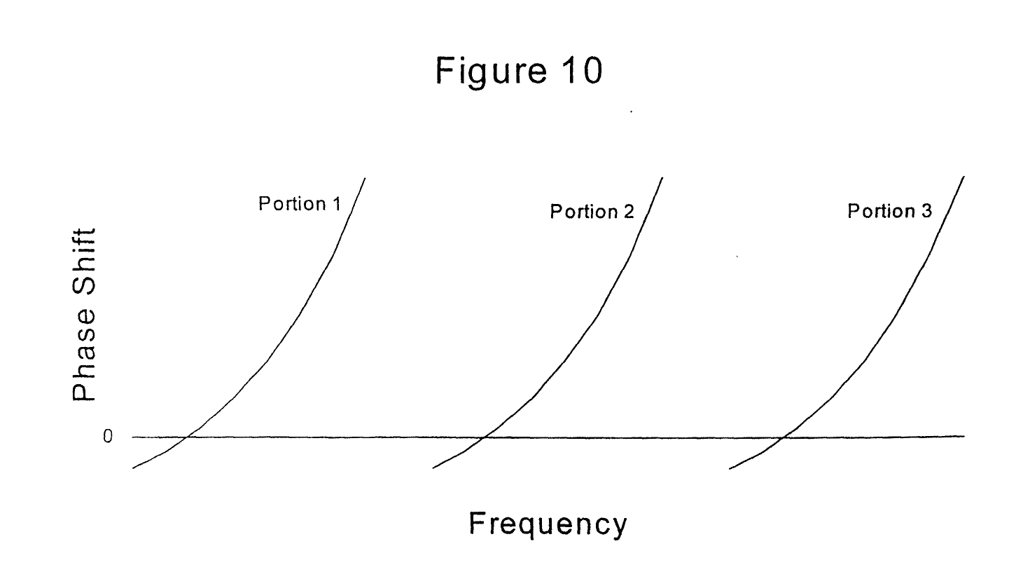

The signal control system 12 introduces a frequency dependent phase shift to the signal and delivers a portion of the signal with the phase shift to each of the amplifiers 14a, 14b and 14c, as described in further detail below. In particular, the signal is divided into three portions—each portion for a selected range of frequencies—and with the phase shift, Δφ, (for each portion of the audio signal) being proportional is the exponential of the frequency, F—as described above with respect to FIG. 3. This is illustrated in FIG. 10, and will be discussed in further detail below.

The signal output from the signal control system 12, is output to respective amplifiers 14a, 14b and 14c, which amplify the respective portions of the signal and deliver the amplified portion directly to the drivers 16a, 16b and 16c, respectively. Because the drivers 16a, 16b and 16c are directly connected to the outputs of the amplifiers 14a, 14b and 14c respectively, the amplifiers 14a, 14b and 14c have accurate control over the motion of the drivers.

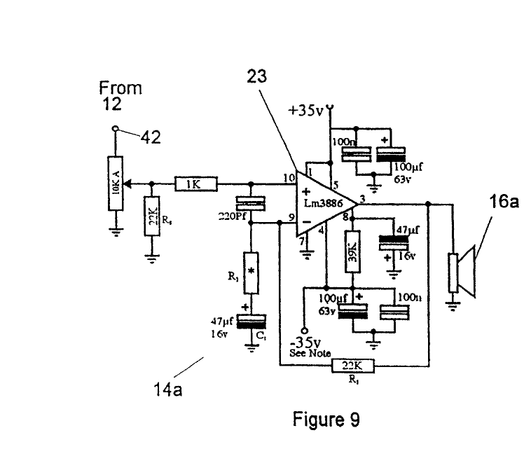

FIG. 9 is a circuit diagram for amplifier 14a. Amplifiers 14b and 14c are, in this embodiment, are the same as the first amplifier 14a. The amplifier 14a receives the output from the signal control system 12 at amplifier input 42, and comprises an LM3886 operational amplifier 23 and associated circuitry as illustrated in FIG. 9. The input signal is amplified and output to its respective driver 16a. The amplifier has a supply voltage Sᵥ, and supply current S_{c}, determined by the impedance of the driver 16a. For a driver 16a with an impedance of 8Ω, and a required output of 60 Watt, then a supply voltage of 35V is required. The minimum gain for the amplifier 14a is determined by the output power, driver impedance, and input voltage level. For an input level of 1V and the above output and driver impedance values, the minimum gain required is approximately 21.9. For an input impedance, R₃ of 22KΩ, then, for the above gain, R₂ and C₁ are set at 1KΩ and 47 μF respectively. No high frequency limiting is required because the bandwidth is set by the signal control system 12. Low frequency limiting—set at about 4 Hz is required to limit low-frequency oscillation and is formed as part of the RC network.

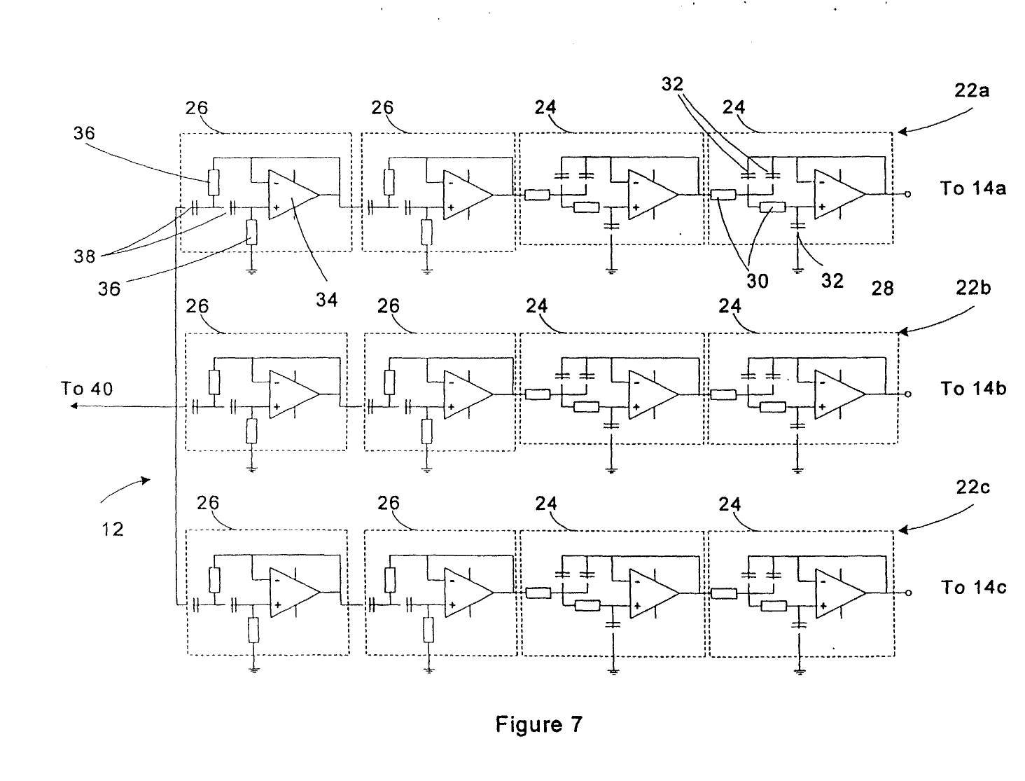

The signal control system 12 will now be described in further detail with reference to FIG. 7, which is a circuit diagram thereof.

The signal control system 12 comprises three sub-circuits 22a, 22b and 22c that are provided between the balanced line receiver 40 and the amplifiers 14a, 14b and 14c, respectively.

Each of the sub-circuits 22a, 22b and 22c comprises a fourth order Butterworth filter comprising low pass stages 24 and high pass stages 26.

Each low pass stage 24 takes the same general form, comprising an operational amplifier 28 (in this embodiment, a TL074 Quad operational Amplifier), resistors 30 and capacitors 32. The values of the capacitors 32 and the resistors 30 are chosen in known manner to provide the low frequency cut-off in each of the sub-circuits 22a, 22b and 22c according to the desired frequency range to be delivered to the corresponding driver. For example, with values of the resistors 30 being selected as 22 kΩ, then the values of the capacitors 32 are selected in accordance with Table 1 below, for the low-pass threshold frequency required:

TABLE 1

| Freq. (Hz) | Cap (F) | Freq. (Hz) | Cap (F) | Freq. (Hz) | Cap (F) |
|---|---|---|---|---|---|
| 15 | 330 n | 108 | 47 n | 1550 | 3 n3 |
| 18 | 270 n | 131 | 39 n | 1895 | 2 n7 |
| 23 | 220 n | 155 | 33 n | 2325 | 2 n2 |
| 28 | 180 n | 189 | 27 n | 2842 | 1 n8 |
| 34 | 150 n | 232 | 22 n | 3410 | 1 n5 |
| 42 | 120 n | 426 | 12 n | 4263 | 1 n2 |
| 51 | 100 n | 511 | 10 n | 5115 | 1 n |
| 62 | 82 n | 913 | 5 n6 | 18946 | 270 pF |
| 75 | 68 n | 1088 | 4 n7 | 23252 | 220 pF |
| 91 | 56 n | 1312 | 3 n9 | 28419 | 180 pF |

Similarly, each of the high pass stages 26 takes the same general form, comprising an operational amplifier 34 (again, in this embodiment, a TL074 Quad operational amplifier), resistors 36a, 36b and capacitors 38. Again, for values of the resistors 36a, 36b being selected as 22 kΩ and 47 kΩ respectively the values of the capacitors 38 are chosen from Table 1 above, according to the selected high frequency cut-off frequency to be delivered to the corresponding driver 16a, 16b, 16c.

The sub-circuits 22a, 22b and 22c form a crossover network for each of the drivers 16a, 16b and 16c respectively. Consequently, the amplifiers 14a, 14b and 14c amplify only the frequencies for the corresponding driver they are connected to. The presence of a crossover circuit before the amplifiers eliminates the need for any crossover circuit between the output of the amplifiers 14a, 14b and 14c and the drivers 16a, 16b and 16c.

Each of the sub-circuits 22a, 22b and 22c also produce a frequency dependent phase shift, Δφ, in the signal as it passes through the circuit. This phase shift, Δφ, introduces the phase shift to the audio signal, as discussed above. This is achieved by using the operational amplifiers 28, 34. The operational amplifier 28, 34 chosen—e.g. the TL074 described above—is not frequency compensated, or is arranged so that frequency compensated pins are not used, thereby not using any frequency compensation aspect of the operational amplifier. In the embodiment, the operational amplifiers 28 and 34 each comprise one operational amplifier in the TL074 quad operational amplifier integrated circuit. Advantageously, the TL074 quad operational amplifier is not frequency compensated and produces a phase shift that increases with increasing frequency. Whereas such an operational amplifier would ordinarily be rejected for audio applications because of its lack of frequency compensation, it has been found that the phase shift introduced by the operational amplifier 28, 34 resulting from its lack of frequency compensation produces a better perception of time alignment at the listener's ear, as described above.

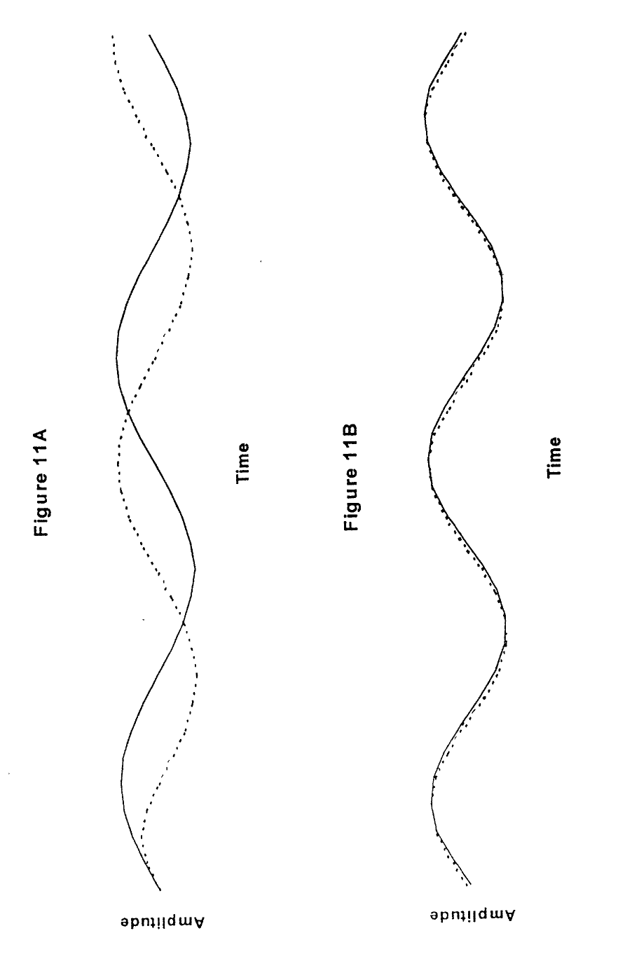

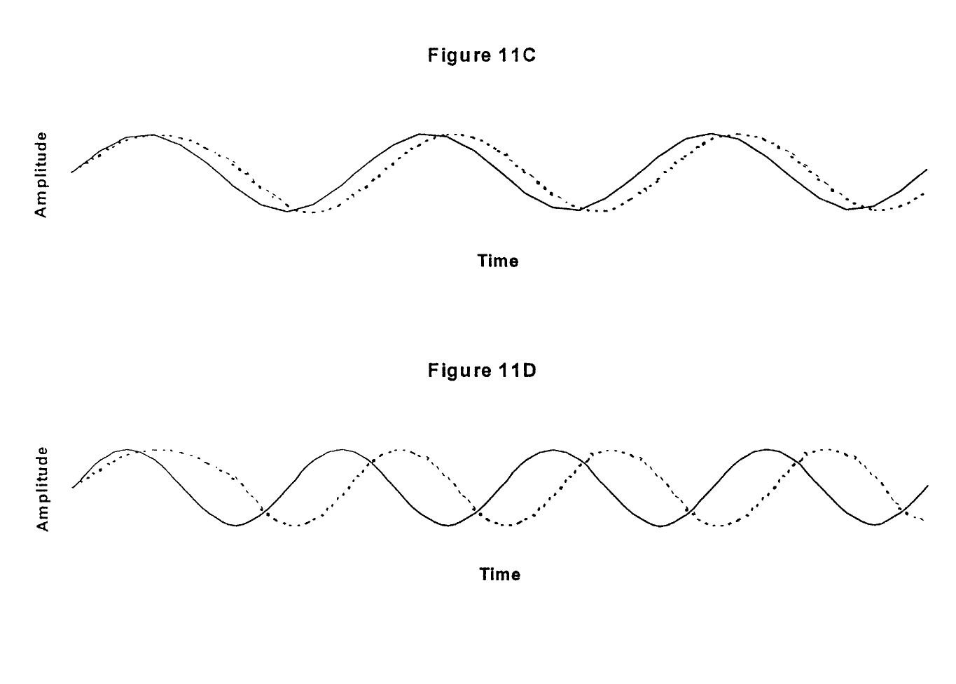

FIGS. 11A to 11D illustrate the extent to which audio signals at selected frequencies input to the signal control system 12 described herein are phase-shifted as they pass through the system 12.

It is possible to measure the phase-shift, Δφ, as a function of frequency, F, for a range of frequencies, and the results are shown in these FIGS. 11A to 11D. All of FIGS. 11A to 11D are graphs of Time vs. Amplitude, A, for sinusoidal audio signals at the input and output, respectively, of the signal control system 12. The input is given by the solid line, and the output by the dotted line. The peak-to-peak separation, Δφ, illustrates the phase shift that has occurred between input and output. For clarity, these drawings are not to scale, but are used purely for illustration.

FIGS. 11A to 11D are for audio signals of 15 Hz, 200 Hz, 1 kHz and 20 kHz respectively.

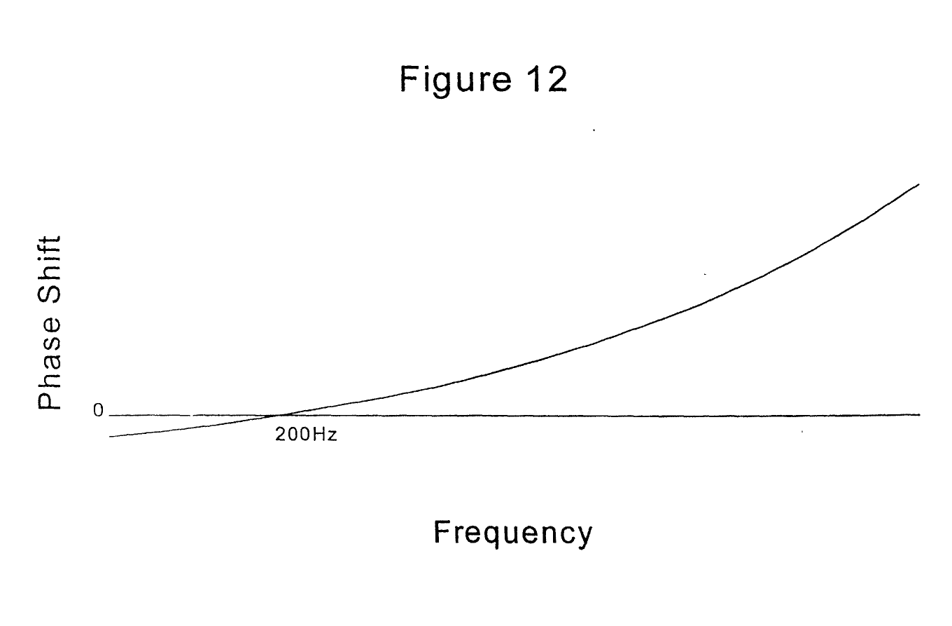

FIG. 12 is a graphical illustration of how the phase-shift, Δφ, changes as a function of frequency. By comparing the FIGS. 11A to 11D, and FIG. 12, it can be seen that the phase-shift, Δφ, changes exponentially as a function of frequency, F. At around a frequency of 200 Hz, the phase-shift, Δφ, becomes zero. Below that frequency, the phase-shift, Δφ, appears to be negative because of a compression of the signal at the start thereof, as shown in FIG. 11A.

The active loudspeakers according to the embodiment are considered to provide superior imaging and depth of sound field to the listener as well as good transient response.

It is envisaged that other circuits may be utilised to provide the frequency dependent phase shift, as discussed with respect to FIGS. 1 to 5 above. Although the embodiment shown in FIG. 7 is particularly advantageous in that the phase shift circuit is integral with the crossover circuit, it is also envisaged that the two circuits could be separated. Further, since the perception of sound is a subjective experience, the amount of phase shift used in the signal control system 12 may be adjusted according to a person's preferences. The quantity of phase shift can be adjusted by increasing or decreasing the number of operational amplifiers 28 and 34 through which the signal passes prior to reaching the input of one of the amplifiers 14. Since each operational amplifier contributes toward the phase shift, increasing the number of operational amplifiers will result in an increased delay. Similarly, digital signal processing, or integrated circuits could be used.

The claims defining the invention are as follows

1. A method of treating an audio signal, comprising introducing a phase shift to the audio signal, the magnitude of the phase shift being dependent upon the frequency of the audio signal.

2. The method of claim 1, further comprising the step of dividing the audio signal into a plurality of portions before introducing the frequency-dependant phase shift, the frequency-dependant phase shift being introduced to each portion.

3. The method of claim 1, wherein the frequency-dependant phase shift has a magnitude that is proportional to the exponential of the frequency of the audio signal.

4. The method of claim 1, wherein the frequency-dependant phase shift has a magnitude that is proportional to the logarithm of the frequency of the audio signal.

5. The method of claim 1, wherein the frequency-dependant phase shift has a magnitude that is linearly proportional to the frequency of the audio signal.

6. The method of claim 1, wherein the frequency-dependant phase shift has a magnitude that is piecewise-linearly proportional to the frequency of the audio signal.

7. The method of claim 1, wherein the frequency-dependant phase shift has a magnitude that is a piecewise-linear approximation of the logarithm of the frequency of the audio signal.

8. The method of claim 1, wherein the frequency-dependant phase shift has a magnitude that is a piecewise-linear approximation of the exponential of the frequency of the audio signal.

9. The method of claim 1, wherein the frequency-dependant phase shift has a magnitude that is monotonically, or piecewise monotonically, dependant upon the frequency of the audio signal.

10. A method as claimed in any preceding claim, wherein the magnitude of the frequency-dependant phase shift is zero at a selected frequency.

11. A signal control system for an active loudspeaker having at least one sound transducer, each sound transducer having an amplifier connected directly thereto, the signal control system provided between a signal source and the amplifier and comprising: crossover means arranged to deliver a frequency limited portion of the signal to the amplifier; and phase shift means arranged to introduce a frequency dependent phase shift to the signal prior to being input to the amplifier, wherein the magnitude of the phase shift is dependant upon the frequency of the audio signal.

12. A signal control system as claimed in claim 11, wherein the phase shift means is provided integral with the crossover means.

13. A signal control system as claimed in claim 12, wherein the crossover means comprises an active crossover circuit, the active crossover circuit comprising a plurality of operational amplifiers and associated bias circuitry, wherein the operational amplifiers are operable without frequency compensation to thereby introduce the frequency dependent phase shift, to the signal.

14. A signal control system as claimed in any one of claims 11 to 13, wherein the active loudspeaker has a plurality of sound transducers, each sound transducer having a corresponding amplifier directly connected thereto, the signal control system comprising a plurality of crossover means and a plurality of phase shift means, a crossover means and a phase shift means being provided between the signal source and each amplifier.

15. A signal control system as claimed in any one of claims 11 to 14, wherein the phase shift means is arranged to introduce a frequency-dependant phase shift to the signal that has a magnitude which is proportional to the exponential of the frequency of the signal.

16. A signal control system as claimed in any one of claims 11 to 14, wherein the phase shift means is arranged to introduce a frequency-dependant phase shift to the signal that has a magnitude which is proportional to the logarithm of the frequency of the signal.

17. A signal control system as claimed in any one of claims 11 to 14, wherein the phase shift means is arranged to introduce a frequency-dependant phase shift to the signal that has a magnitude which is linearly proportional to the frequency of the signal.

18. A signal control system as claimed in any one of claims 11 to 14, wherein the phase shift means is arranged to introduce a frequency-dependant phase shift to the signal that has a magnitude which is piecewise-linearly proportional to the frequency of the audio signal.

19. A signal control system as claimed in any one of claims 11 to 14, wherein the phase shift means is arranged to introduce a frequency-dependant phase shift to the signal that has a magnitude which a piecewise-linear approximation of the logarithm of the frequency of the audio signal.

20. A signal control system as claimed in any one of claims 11 to 14, wherein the phase shift means is arranged to introduce a frequency-dependant phase shift to the signal that has a magnitude which is a piecewise-linear approximation of the exponential of the frequency of the audio signal.

21. A signal control system as claimed in any one of claims 11 to 14, wherein the phase shift means is arranged to introduce a frequency-dependant phase shift to the signal that has a magnitude which is monotonically, or piecewise monotonically, dependant upon the frequency of the audio signal.

22. A signal control system as claimed in any of claims 11 to 21, wherein the phase shift means is arranged to introduce a frequency-dependant phase shift that has a magnitude of zero at a selected frequency.

23. An active loudspeaker circuit provided between a signal source and a plurality of amplifiers, comprising: crossover means arranged to deliver a frequency limited portion of the signal to each amplifier; and phase shift means arranged to introduce a frequency dependent phase shift to the signal prior to being input to the amplifiers, wherein the frequency dependent phase shift increases with increasing frequency.

24. An active loudspeaker circuit as claimed in claim 23, wherein the phase shift means is arranged to introduce a frequency-dependant phase shift that has a magnitude of zero at a selected frequency.
